(19) United States
(12) Patent Application Publication
(10) Pub. No.: US 2026/0319021 A1
(43) Pub. Date: Oct. 15, 2026

(54) METHOD AND DEVICE FOR TESTING A TRANSFORMER

(71) Applicant: Omicron electronics GmbH, Klaus (AT)

(72) Inventors: Dmitry Atlas, Bregenz (AT); Thomas Bischof, Rankweil (AT); Andreas Claus, Wasserburg (DE); Dirk Flax, Dornbirn (AT)

(21) Appl. No.: 19/166,026

(22) PCT Filed: Mar. 6, 2024
(86) PCT No.: PCT/EP2024/055811

§ 371 Date: Sep. 16, 2025

(30) Foreign Application Priority Data
Mar. 17, 2023 (AT) A50204/2023

(51) Int. Cl. G01R 31/62; G01R 19/12; G01R 27/26; G01R 33/14

(52) U.S. Cl. CPC G01R 31/62; G01R 19/12; G01R 27/2605; G01R 33/14

(57) ABSTRACT

The present invention relates to a method (200) for testing a transformer (180). The method comprises determining (202) an edge steepness for a test signal (702) as a function of the transformer (180) to be tested and generating (204) the test signal (702) with the determined edge steepness. The method further comprises testing (206) the transformer (180) using the generated test signal (702).

### FIELD OF THE INVENTION

The present invention relates to a method and a correspondingly configured device for testing a transformer. In particular, the present invention is suitable for tests and measurements on transformers used as current transformers. Testing the transformer may comprise, for example, measurements of magnetization curves.

### BACKGROUND OF THE INVENTION

In energy technology, measuring transformers, in particular current transformers, are used, which are based on a transformer designed to meet the measurement requirements, which enables potential-free measurement of large alternating currents under high electrical voltage. In order to ensure a proper condition of a current transformer, requirements for the current transformer must be checked, which are defined, for example, in the standard EN 61869-2. These requirements relate, among other things, to magnetization parameters, wherein in particular a magnetization curve and a saturation magnetization may be relevant.

For this purpose, a test device can generate, for example, a sinusoidal signal with mains frequency, which is fed into the device under test, for example a current transformer. As a result, voltages and currents, which also occur in nominal operation, can be generated on the secondary side of the current transformer. Therefore, test signals with a power of up to 5 KW, for example, are therefore required in the case of conventional current transformers. These test devices are very heavy due to this high output power or they can only test current transformers for small powers.

In addition, there are test methods in which test signals with a reduced test frequency or test voltage are used to test the respective current transformer. However, these are generally very inaccurate, since the changed behaviour of current transformers is not sufficiently taken into account when operating at a frequency that deviates from the nominal or mains frequency.

In this context, EP 1398644B1 discloses a method for testing a transformer, in which a test signal whose frequency is lower than the rated or operating frequency of the transformer is applied to the transformer in order to measure a plurality of, in particular, frequency-dependent parameters of the transformer. A simulation model is derived from the parameters measured with this test signal, which makes it possible to simulate the behaviour of the transformer at different frequencies. With the aid of this simulation model or the parameters measured with the test signal, it is then possible to infer the behaviour of the transformer during operation at a frequency deviating from the frequency of the test signal, for example the behaviour of the transformer during operation at nominal frequency. In particular, a rectangular signal whose fundamental frequency is less than the nominal frequency can be used as the test signal.

The use of rectangular signals is particularly suitable for achieving a correspondingly large magnetic flux in the magnetic core. In this case, however, the problem may arise that capacitive current peaks occur at high edge steepnesses of the rectangular signal in combination with high voltages in transducers with a high parasitic capacitance due to their design. These currents can overload the test device or require correspondingly higher sized and thus more expensive and heavier test devices. In addition, this can impair the precision of the measurement.

### SUMMARY OF THE INVENTION

It is therefore an object of the present invention to provide a precise measurement of magnetization parameters of a transformer, in particular a magnetization curve of a current transformer, which can be implemented cost-effectively and is suitable for a large spectrum of transducers.

This object is achieved according to the invention by methods for testing a transformer and a correspondingly configured device for testing a transformer as defined in the independent claims. The dependent claims define advantageous embodiments of the present invention.

According to the invention, in a method for testing a transformer, an edge steepness for a test signal is determined as a function of the transformer to be tested, and the test signal is generated with the edge steepness thus determined. The transformer is tested using the generated test signal.

In other words, a test signal with a signal form which has an edge steepness dependent on the transformer to be tested is used. The used signal form of the test signal thus has defined harmonics, i.e. defined components of frequencies above a fundamental frequency of the test signal. In particular, it can be achieved thereby that the signal form of the test signal has fewer frequency components than, for example, a rectangular signal, as is usually generated by means of constant voltage sources connected in a bridge. Furthermore, undershoot and overshoot can be avoided or reduced by adjusting the edge steepness. The edge steepness of the test signal is not determined by a switching mechanism used in the test signal generation, but rather it is adjusted as a function of the transformer. A correspondingly controllable signal source can be used for this purpose. Due to the adjustable edge steepness, in particular a lower edge steepness compared to connected constant voltage sources, large capacitive current peaks can be avoided and thus, on the one hand, an overload of the device that generates the test signal can be avoided and, on the other hand, an accuracy of the measurement can be increased, since the currents to be measured occur in a limited range, which can thus be accurately acquired. By determining and adjusting the edge steepness as a function of the transformer, it is also possible, for example, to test current transformers with a high capacitance as a result of the design; in particular, a magnetization curve can be measured accurately, for example.

The test signal can be generated, for example, by actuating at least one adjustable voltage converter. The voltage converter can be, for example, a direct voltage converter, a so-called DC-DC converter. In order to generate an alternating voltage with the desired edge steepness, for example, two voltage converters can be used. One of the two voltage converters generates an adjustable grounded positive voltage and the other of the two voltage converters generates a grounded adjustable negative voltage. The adjustable positive voltage and the adjustable negative voltage are each adjustable by a control device to a plurality of voltage values and are supplied to the transformer to be tested. The previously determined edge steepnesses for rising and dropping edges can be realized via a corresponding adjustment of the voltage over time. An adjustable range of the output voltage of the voltage converters can be, for example, from zero to 25 V or from zero to 50 V, for example in steps of 1 V or 0.1 V.

Due to the adjustable grounded positive and negative voltages, an iron core of the transformer can be magnetized in both directions, for example, in order to measure magnetization curves.

For example, a parasitic capacitance of the transformer can be determined in order to determine the edge steepness for the test signal. Depending on the parasitic capacitance and a predetermined maximum current which can occur during testing of the transformer, the edge steepness can be determined. Parasitic capacitances can occur, for example, due to connection lines, connection terminals and the structure of the transformer. These capacitances can lead to current peaks, especially at high frequencies. By adjusting the edge steepness for the test signal, high frequencies can be avoided, for example by reducing the edge steepness. This means that current peaks can be avoided. The test device is less heavily loaded because it has to provide a lower maximum current. As a result, the reliability of the test device can be improved and the test device can be made more compact and lighter.

The parasitic capacitance can be determined by a measurement on the transformer to be tested. In particular, for example, a high-frequency measurement can be carried out on the transformer. A high-frequency measurement on the transformer means, for example, that a frequency at which the parasitic capacitance is measured is higher than the nominal frequency, for example, is a multiple of the nominal frequency. The nominal frequency of the transformer may be 50 or 60 Hz, for example. The high frequency used in the measurement of the parasitic capacitance may, for example, be more than 1 kHz or even more than 100 kHz. A voltage used in this case can be correspondingly low, in particular lower than the voltage to be used when testing the transformer. For example, the transformer can be tested at +/−25 V, whereas the parasitic capacitance is measured at +/−5 V.

Alternatively or additionally, the parasitic capacitance may be input by a user. The user may have determined the value of the parasitic capacitance with an additional measuring device, for example, or the parasitic capacitance may be stored in a database. Furthermore, a type of the transformer to be tested and, if necessary, its connection configurations can be entered, whereupon the parasitic capacitance can be retrieved from a database, for example.

It is clear that a currently measured parasitic capacitance is advantageous, since in this case actual states of the transformer are taken into account and the edge steepness can be optimally adjusted for the test signal. A correspondingly configured test device can, for example, first automatically determine the parasitic capacitance by measurement and then begin the actual test of the transformer, for example a measurement of a magnetization curve of the transformer, using the edge steepness determined from the parasitic capacitance. Taking parasitic capacitance into account can increase measurement accuracy. On the one hand, current peaks due to the parasitic capacitance can be reduced and determined by the selected edge steepness, so that a distinction can be made between regular inductive current through the transformer and capacitive current peaks. For example, a magnetization curve of the transformer can then be measured with great precision using the regular inductive current thus determined.

According to an embodiment, the test signal is a periodic test signal. The edge steepness can be determined using an iterative method. In the iterative method, an edge steepness for a subsequent period of the test signal is determined based on an edge steepness in a period of the test signal as a function of a measured maximum current generated during testing of the transformer with the test signal in the previous period. For example, the edge steepness may be slightly increased from one period to the next period. For example, starting from a relatively low edge steepness, the edge steepness may be slowly increased, thereby increasing the capacitive current peaks. This can be continued until a desired or permissible maximum current is reached. The maximum current may correspond, for example, to a nominal current of the test device or a certain percentage of the maximum current of the test device, for example, 90% of the maximum current. As soon as the edge steepness has been determined with the aid of this iterative method, the measurement can be carried out on the transformer with the edge steepness determined in this way.

The test signal may be, for example, a periodic voltage signal. Per period, the voltage signal may comprise a voltage rise with the determined edge steepness from a lower voltage value to an upper voltage value, an upper portion with substantially constant voltage at the upper voltage value, and a voltage drop from the upper voltage value to the lower voltage value. It is clear that the lower voltage value is less than the upper voltage value. The lower voltage value may be grounded negative, for example, and the upper voltage value may be grounded positive. The amounts of upper voltage value and lower voltage value may be different or the same. The voltage signal may have a lower portion with a substantially constant voltage at the lower voltage value per period. A length of the lower portion and a length of the upper portion may be substantially equal. The voltage drop can have an edge steepness that is equal in magnitude to the edge steepness of the voltage rise.

It is understood that the lower portion may also have a different length than the upper portion. Likewise, the voltage drop may have a different edge steepness in terms of magnitude than the voltage rise. However, in many embodiments, the upper portion will have substantially the same length as the lower portion, and the edges of the voltage drop and the voltage rise will have substantially the same steepness in terms of magnitude. In these cases, the voltage signal is symmetrical to ground.

The edge steepness can be constant over the rise time or the descent time, so that the test signal has a trapezoidal signal course. However, the edge steepness can also vary over the rise time or drop time, for example, beginning with a steepness that is low in terms of magnitude, which then increases and reaches its maximum in the region of the zero crossing of the voltage signal, in order to then become lower again. This results in a trapezoidal signal course with “soft” transitions between the substantially constant plateau portions and the edges.

According to further embodiments, a time at which an edge of the test signal begins is adjusted or initiated depending on a comparison of a current generated by the test signal through the transformer with a threshold value. As described above, the test signal may be periodic with a substantially constant upper portion and a substantially constant lower portion. An edge of the test signal begins when, for example, a voltage drops from the substantially upper (positive) voltage value or a voltage rises from the substantially lower voltage value. In a test of the transformer, for example, the substantially constant voltage in the upper portion causes a (positive) current through a winding of the transformer to rise due to the inductance of this winding. The current through the winding may be measured and, when the current reaches the threshold value, a voltage drop may be initiated at the previously determined edge steepness. However, as long as the voltage is still positive during the dropping edge, the current through the winding continues to increase. The current through the winding is reduced only after the zero crossing of the voltage. The voltage reaches the lower (negative) voltage value and then remains substantially constant. The (positive) current is further reduced, becomes zero and then flows in the opposite direction (negative current) through the winding and increases in terms of magnitude, while the voltage value remains substantially constant at the lower voltage value. As soon as the (negative) current through the winding has reached in terms of magnitude the threshold value, the rising edge begins. As long as the voltage is still negative during the rising edge, the (negative) current continues to increase in magnitude.

Only when the rising edge reaches the zero crossing and then a positive voltage is again applied to the transformer does the (negative) current decrease in magnitude. While the voltage has the substantially constant upper (positive) voltage value, the (negative) current initially drops to zero in terms of magnitude and then rises again in the opposite direction (positive current) in terms of magnitude until it reaches the threshold value. Then the above-described cycle starts again.

As described above, the current initially continues to increase in magnitude even with the onset of the edges, since the edges do not have an infinite steepness and the voltage therefore remains positive (with dropping edge) or negative (with rising edge) until the zero crossing. Rather, the edge steepness is relatively low, so that high-frequency components are not included in order to avoid current peaks due to the parasitic capacitances. The further current rise even after the onset of the edges is therefore unavoidable and must be taken into account in order not to exceed a desired maximum current. For example, to avoid overloading the test device. The amount of the threshold value at which the edges are initiated can therefore be set to an amount of a maximum nominal current of the test device, which provides the test signal, for example to a value in the range of 70 to 95% of the nominal current, for example to 90% of the nominal current, or depending on an expected further increase in the inductive current, which, however, in turn depends on the set edge steepness.

For example, the amount of the threshold value may be adjusted dynamically depending on an observation of the actual current through the transformer. For example, the threshold value may be determined as a function of the edge steepness of the test signal, a voltage swing of the test signal, and an absolute current rise of a current generated by the test signal through the transformer. The voltage swing of the test signal is, for example, the voltage distance between the upper and lower voltage values in the case of a periodic test signal. Assuming, for example, that the edge steepness is constant, i.e. that the voltage drop per unit time is constant from the beginning to the end of the edge, the time from the beginning of the edge to the voltage zero crossing can be determined in a simple manner. Even if the edge does not have a constant edge steepness, the time from the beginning of the edge to the voltage zero crossing can be determined since the edge shape is determined and adjusted.

During this time, as discussed above, the current through the transformer continues to increase at least due to the inductance of the winding of the transformer. In addition, the current through the parasitic capacitances can increase. The current rise of the current flowing through the transformer can be measured, for example, by continuously measuring the current during the test of the transformer and determining the corresponding current change, that is, change in the current per unit time. Continuously can mean, for example, that the current is continuously measured at short time intervals of, for example, 1 μs and the current change is determined from the change in the current per microsecond. The maximum period of time over which the current can continue to rise results from the time from the beginning of the edge till the voltage zero crossing. An estimate of the further voltage rise achievable during this time can be made, for example, by multiplying the last determined current rise by this time from the beginning of the edge till the voltage zero crossing. Based on this estimate, the threshold value can be set so that the current does not exceed a desired maximum value, for example, the maximum nominal current of the test device. In other words, the threshold value may be determined as a difference between an amount of a desired maximum current generated by the test signal through the transformer and a product of the actual current rise and a polarity reversal time of the test signal. The polarity reversal time depends on the voltage swing of the test signal and the edge steepness.

An additional reserve of, for example, 10% of the maximum current can be provided for an additional current due to the parasitic capacitances. However, this reserve can be kept relatively small since, due to the purposefully adjusted edge steepnesses, the additional current due to the parasitic capacitances is relatively small compared to corresponding current peaks due to edge steepnesses obtained by simply switching the test signal between the upper and lower voltage values.

According to an embodiment, testing may comprise determining a magnetization curve of the transformer as a function of the periodic voltage signal and a time course of a current generated by the voltage signal through the transformer.

According to the present invention, there is further provided a device for testing a transformer, that is, a test device. The device comprises a test signal source for generating a test signal for the transformer and a processing device coupled to the test signal source. The processing device is configured to determine an edge steepness for the test signal as a function of the transformer to be tested, to generate the test signal with the edge steepness thus determined by means of the test signal source, and to test the transformer using the generated test signal. The device is thus suitable for carrying out the method described above and therefore also comprises the advantages described above.

The features of the above-described embodiments and aspects of the invention may be arbitrarily combined with one another, unless expressly stated otherwise. In particular, the features can be used not only in the described combinations, but also in other combinations or on their own.

### BRIEF DESCRIPTION OF THE FIGURES

The present invention will be described in detail below with reference to the attached figures.

FIG. 1 schematically shows a device for testing a transformer according to an embodiment of the present invention in conjunction with a transformer.

FIG. 2 schematically shows method steps of a method for testing a transformer according to an embodiment of the present invention.

FIG. 3 schematically shows a test signal source according to an embodiment of the present invention.

FIG. 4 schematically shows a test signal source according to another embodiment of the present invention.

FIG. 5 schematically shows yet another test signal source according to yet another embodiment of the present invention.

FIG. 6 schematically shows a voltage course of a test signal fed into a transformer and an associated current course.

FIG. 7 schematically shows a voltage course of a test signal fed into a transformer, with an edge steepness determined according to an embodiment of the present invention, and an associated current course.

FIG. 8 schematically shows method steps for determining an edge steepness according to an embodiment of the present invention.

FIG. 9 schematically shows a determination of a threshold value from a current course used to determine a time at which an edge of the test signal begins.

### DETAILED DESCRIPTION OF EXAMPLE EMBODIMENTS

The above-described properties, features, and advantages of this invention, as well as the manner in which they are achieved, will become clearer and more comprehensible in connection with the following description of embodiment examples, which will be explained in more detail in connection with the drawings.

In the following, the invention will be specified in greater detail in the context of embodiment examples, with reference to the drawings. In the figures, the same reference numerals designate the same or similar elements. The figures are schematic representations of various embodiments of the invention. Elements depicted in the figures are not necessarily depicted to scale. The various elements depicted in the figures are reproduced in such a way that their function and their general purpose are understandable to a person skilled in the art. Connections and couplings between functional units and elements depicted in the figures may also be implemented as an indirect connection or coupling. Functional units can be implemented as hardware, software or a combination of hardware and software.

FIG. 1 shows a transformer 180 in conjunction with a device 100 for testing the transformer 180. The transformer 180 may be, for example, a current transformer, which is provided in a power engineering electrical system. The device 100 may be coupled to a secondary side of the transformer 180, for example. The device 100 may comprise, for example, a portable test device that is transported to the transformer 180 for testing the transformer 180 and is coupled to the transformer 180 via lines 150, 152. In this context, the transformer to be tested is also referred to as the device under test (DUT).

The device 100 comprises a test signal source 102 and a processing device 104. The processing device 104 may comprise, for example, a microprocessor controller comprising a working memory, a mass memory for program code and data, and input/output devices. Further, the device 100 may comprise a user interface 106 and a current measuring device 108. The user interface 106 may include, for example, an optionally touch-sensitive screen, a keyboard or keys, a speaker, signal lights, and the like. The current measuring device 108 may be provided, for example, in or on a line to the transformer 180, e.g., in the line 152, in order to measure a current flowing through the transformer 180, which current flows on the basis of a voltage generated by the test signal source 102. The current measuring device 108 may comprise an analogue/digital converter that determines the current intensity at a predetermined sampling frequency and provides it as a corresponding digital value to the processing device 104. The test signal source 102, the user interface 106, and the current measuring device 108 are coupled to and controlled by the processing device 104 and/or provide measurements and other information to the processing device 104, such as user inputs. The device 100 may comprise further components, for example a power supply device for supplying electrical energy to the components described above, as well as further measuring devices for measuring current, voltage, or power on the lines 150, 152. The device 100, in particular the processing device 104, can be configured to carry out the methods and techniques described below. The device 100 can also be configured to carry out further tests on other devices under test, for example high-voltage switches, electrical bushings or electrical lines.

When testing a transformer, it may be necessary to feed test signals into the transformer that do not correspond to the nominal signals. For example, these test signals may have frequencies lower or higher than the nominal frequency of the transformer. As a result, properties of the transformer can be tested that cannot be tested at nominal frequency or can only be tested with great effort, for example saturation magnetization. Possible test signals are sinusoidal signals and, in particular for determining a saturation magnetization, also rectangular signals, which, however, also contain very high-frequency components. A test signal may be, for example, a voltage signal. As a reaction, a current flows, the time course of which, i.e. the current intensity as a function of time, can be acquired by means of the current measuring device 108. A model can be used to calculate back to the corresponding nominal values from the results of the test signals. The use of rectangular signals is particularly necessary for achieving a correspondingly large magnetic flux in the magnetic core. However, the high edge steepnesses of the rectangular signal lead to large capacitive current peaks in conjunction with structure-related parasitic capacitances. The parasitic capacitances can arise, for example, from the connections and connection lines as well as the structure of the transformer itself. The large current peaks may overload the test signal source 102 and/or affect the accuracy of the measurement.

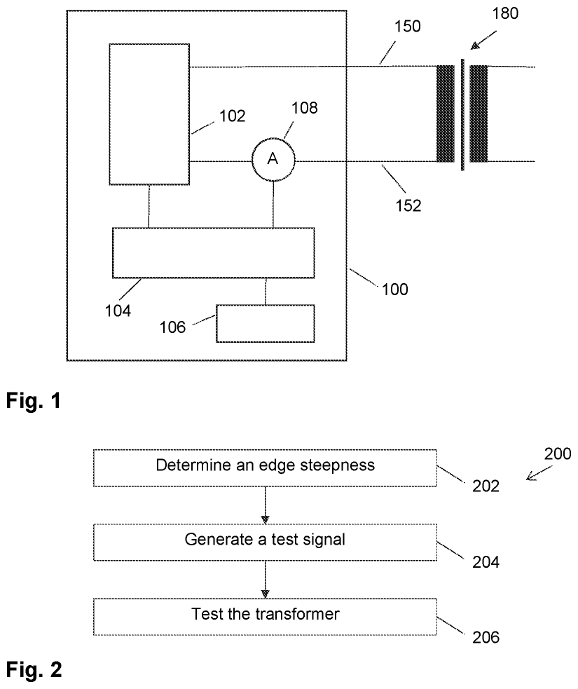

Therefore, the test signal source 102 generates a test signal in which the high-frequency components are reduced compared to a switched rectangular signal, i.e., a test signal with defined rising and dropping edges. For example, instead of a simple rectangular signal, a combination of triangular and rectangular signals can be generated, i.e. a test signal with a trapezoidal shape. In order to nevertheless have as long as possible portions with a constant voltage in the test signal, for example in order to achieve a saturation magnetization, and in addition in order to be able to provide high-frequency components in the test signal, which can be used, for example, by the model for determining properties of the transformer, a method 200, as shown in FIG. 2, is carried out, for example, under the control of the processing device 104.

In the method 200, in step 202, an edge steepness for the test signal is determined as a function of the transformer 180 to be tested, and in step 204, the test signal with the determined edge steepness is generated by means of the test signal source 102. The transformer 180 is then tested using the generated test signal in step 206. The aim is to determine the edge steepness for the test signal such that long portions with constant voltage and high-frequency components are included in the test signal, but without overloading the test signal source 102 due to capacitive current peaks and impairing the accuracy of the measurement.

Technically, the test signal with the adjustable edge steepness can be realized by using one or more voltage sources having an adjustable output voltage. In a conventional generation of a rectangular signal, for example, two DC voltage sources with a fixed output voltage can be used. One of the DC voltage sources has, for example, a grounded positive output voltage and the other DC voltage source has a grounded negative output voltage. In terms of magnitude, the two output voltages can be the same. For example, a changeover switch or two switches connect either the DC voltage source to the positive output voltage or the DC voltage source to the negative output voltage to one terminal of a winding of the transformer, while the other terminal of the winding of the transformer is connected to ground. However, it is not possible here to adjust the edge steepness.

The test signal with the adjustable edge steepness can be generated, for example, by using and actuating at least one adjustable voltage converter. The voltage converter may be, for example, a direct current voltage converter, a so-called DC/DC converter. The adjustable voltage converter may be selectively adjustable to one of a plurality of voltage values, for example, to a voltage between zero volts and 25 V or 50 V with an accuracy of 1 V or 0.1 V, for example, under the control of the processing device 104. For example, the voltage converter may comprise a clocked or linear DC amplifier (DC-DC amplifier) that may generate positive and/or negative output voltages. The voltage converter or amplifier is able to provide the necessary voltages and currents with the necessary dynamics.

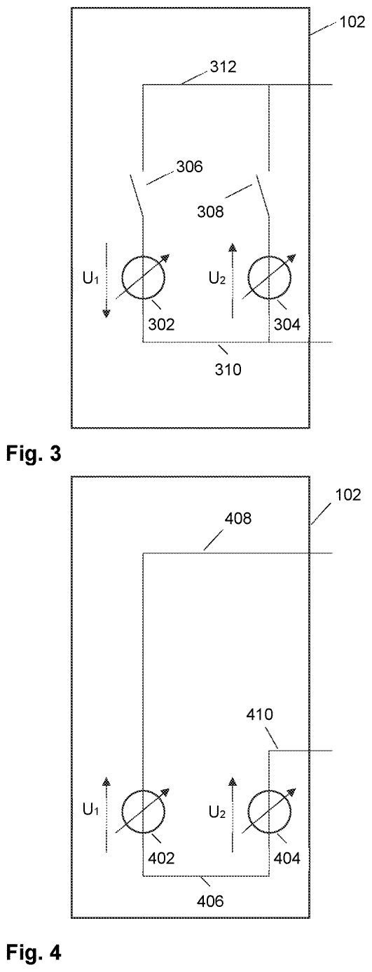

FIG. 3 schematically shows an example of a realization of the test signal source 102. In this example, the test signal source 102 comprises two adjustable voltage converters 302, 304 and two switches 306, 308. The switches 306, 308 may be mechanical or electronic switches controllable by means of the control device 104. The voltage converter 302 is configured, for example, to output an output voltage U₁, which is negative with respect to a ground line 310 and can be set in terms of magnitude to a plurality of values between zero and a maximum voltage Uₘₐₓ. Uₘₐₓ can be in a range of 10 V to 100 V, for example. For example, Uₘₐₓ may be 25 V. The voltage converter 304 is configured, for example, to supply an output voltage U₂, which is positive with respect to the ground line 310 and can be set in terms of magnitude to a plurality of values between zero and Uₘₐₓ. The output voltages of the voltage converters 302, 304 may be adjusted by the control device 104. Via the switches 306, 308, the output voltage from the voltage converter 302 or the output voltage from the voltage converter 304 can be selectively connected to the line 312. By suitably actuating the voltage converters 302, 304 and the switches 306, 308, an alternating voltage in the range of −Uₘₐₓ to +Uₘₐₓ may be provided on the lines 310, 312, which may be used to test the transformer 180, as shown in FIG. 1. For example, a periodic trapezoidal AC voltage may be provided. A fundamental frequency of this periodic alternating voltage may, for example, correspond to a nominal frequency of the transformer 180, for example 50 Hz or 60 Hz. It is understood that the fundamental frequency may have any other value above or below the nominal frequency of the transformer, for example, 30 Hz or 100 Hz. Within one period, the alternating voltage can have, for example, the following voltage course: (1) a voltage rise with a desired edge steepness from a lower voltage value, for example −Uₘₐₓ, to an upper voltage value, for example +Uₘₐₓ; (2) an upper portion with substantially constant voltage at the upper voltage value; (3) a voltage drop from the upper voltage value to the lower voltage value with a desired edge steepness; and (4) a lower portion with substantially constant voltage at the lower voltage value. It is clear that the lower voltage value and the upper voltage value can be different in terms of magnitude. Likewise, it is clear that the edge steepness from the lower voltage value to the upper voltage value may be different than the edge steepness from the upper voltage value to the lower voltage value. In many examples, however, the lower voltage value is equal in magnitude to the upper voltage value and the edge steepness of the voltage rise is equal in magnitude to the edge steepness of the voltage drop.

In the case of a voltage swing between the upper voltage value and the lower voltage value of, for example, 50 V, the desired edge steepness can be, for example, 50 V per 28 μs. A period of an exemplary test signal at 50 Hz is 20 ms, so that the lower and upper portions are each just under 10 ms long (exactly 9.972 ms).

FIG. 4 schematically shows a further example of a realization of the test signal source 102. In this example, the test signal source comprises two adjustable voltage converters 402, 404. The adjustable voltage converter 402 is configured to provide an adjustable output voltage U₁ on the line 408 that is positive with respect to a connection line 406 connecting the two adjustable voltage converters 402, 404 and is adjustable in terms of magnitude to a plurality of values between zero and Uₘₐₓ. The adjustable voltage converter 404 is configured to provide an adjustable output voltage U₂ on the line 410, which is also positive with respect to the connection line 406 and is adjustable in terms of magnitude to a plurality of values between zero and Uₘₐₓ. By suitably actuating the voltage converters 402, 404 by means of the control device 104, an alternating voltage with a voltage swing of 2×Uₘₐₓ and adjustable edge steepness can be generated on the lines 408, 410.

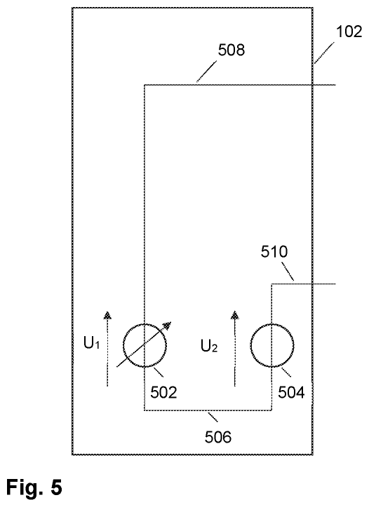

FIG. 5 schematically shows yet another example of a realization of the test signal source 102. In this example, the test signal source comprises an adjustable voltage converter 502 and a fixed voltage source 504. The adjustable voltage converter 502 is configured to provide, by actuation by means of the control device 104, an adjustable output voltage U₁ on the line 508, which is positive with respect to a connection line 506 connecting the voltage converter 502 to the fixed voltage source 504, and is adjustable in terms of magnitude to a plurality of values between zero and 2×Uₘₐₓ. The fixed voltage source 504 is configured to provide a fixed output voltage U₂ on the line 510, which is also positive with respect to the connection line 506 and has the value Uₘₐₓ, for example. By suitably actuating the voltage converter 502, an alternating voltage with a voltage swing of 2×Uₘₐₓ and adjustable edge steepness can be generated on the lines 508, 510.

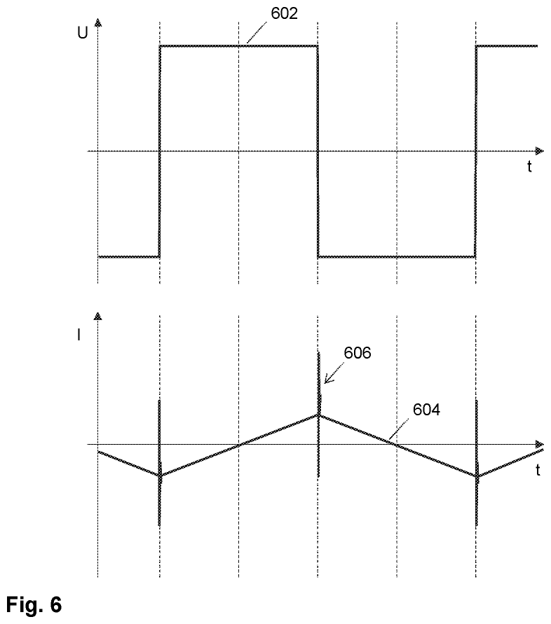

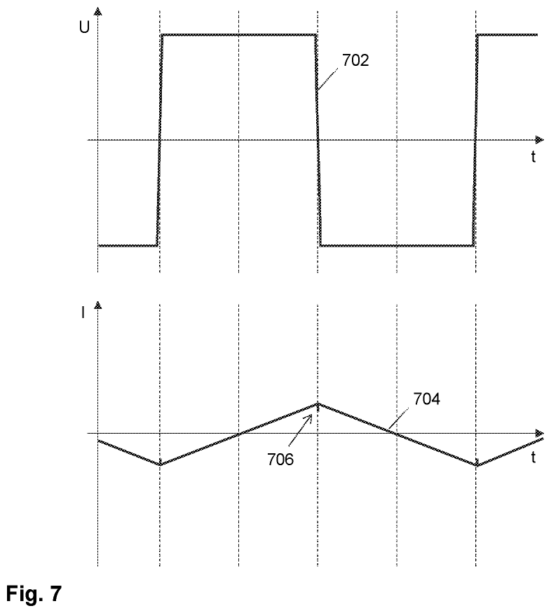

FIGS. 6 and 7 show, schematically and by way of example, signal courses 602, 702 of an output voltage of the test signal source 102, as can be generated in the test signal source 102 by suitable actuation of the above-described voltage converters. FIGS. 6 and 7 each show in the upper part the signal course 602, 702 of the output voltage and in the lower part a respective signal course 604, 704 of a current through the transformer 180 connected to the test signal source 102. The signal course 604, 704 of the current through the transformer 180 may be measured, for example, by means of the current measuring device 108 (see FIG. 1). The output voltage may, for example, have a voltage swing of 50 V, that is, the upper voltage level is, for example, +25 V and the lower voltage level is, for example, −25 V. In the example, an ohmic resistance of the transformer 180 is 220 mΩ and an inductance is 0.5 H. The frequency of the output voltage is substantially 50 Hz. Without taking into account the capacitive current peaks described below, the inductive current between the signal edges, i.e. during the upper and lower signal portions with a substantially constant voltage, increases in magnitude to, for example, approx. 250 mA.

The signal course 602 of the output voltage shown in FIG. 6 has very steep signal edges. The voltage swing of the voltage depicted in FIG. 6 may be 50 V, for example, and the edge steepness may be 25 V/μs or more, for example, 50 V/μs, for example. Due to the parasitic capacitances, which can be generated, for example, by lines and terminals of the transformer as well as by the structure of the transformer itself, very high currents 606, so-called current peaks, occur during the signal edge, as shown in the lower part of FIG. 6. These high currents are caused by high-frequency components of the steep signal edges, which enable high capacitive currents. An amount of these current peaks may be substantially higher than an amount of inductive current, for example, 500 mA, 1000 mA, or greater.

The signal course 702 of the output voltage shown in FIG. 7 has less steep signal edges. In the case of a voltage swing of again, for example, 50 V, the edge steepness can be, for example, 50 V/20 μs or less, for example, 50 V/28 μs. As can be seen from the signal course 704 of the corresponding current shown in FIG. 7, significantly lower current peaks 706 occur at this lower edge steepness, since the signal edges now have significantly lower amplitudes at the high-frequency components. The capacitive current peaks 706 become correspondingly smaller, for example only 50 mA or 100 mA.

A current I_{C} of a capacitive current peak depends on the parasitic capacitance C of the transformer 180 as follows:

$${I}_{C} = C \frac{d u}{d t} \qquad ( Equation 1 )$$

In practice, values for the parasitic capacitance often occur in the range between 100 pF to 30 nF, but are not limited to this range and can therefore be quite larger or smaller, for example 3 μF. Therefore, the edge steepness to be used is determined and set as a function of the transformer currently being tested. In this regard, various procedures are described below.

In a procedure for determining the edge steepness, the parasitic capacitance of the transformer is first determined. For this purpose, for example, the parasitic capacitance can be measured by means of a high-frequency measurement on the transformer. The high-frequency measurement may be performed at a lower voltage than the later test voltage, for example, to ensure that the device 100 is not overloaded. The parasitic capacitance may also be provided via input from a user via the user interface 106. For example, the user may directly input the parasitic capacitance from information about the transformer, or the user may input a type of the transformer, and the parasitic capacitance may be determined from a database based on the type of the transformer, for example. The edge steepness can then be determined as a function of the parasitic capacitance and a predetermined maximum capacitive current, which should not be exceeded during testing of the transformer. The maximum capacitive current can be determined, for example, from a maximum nominal current of the test signal source 102 and a maximum inductive current occurring during the measurement of the transformer, for example, as the difference between these two currents. The edge steepness du/dt can then be determined from the above equation 1.

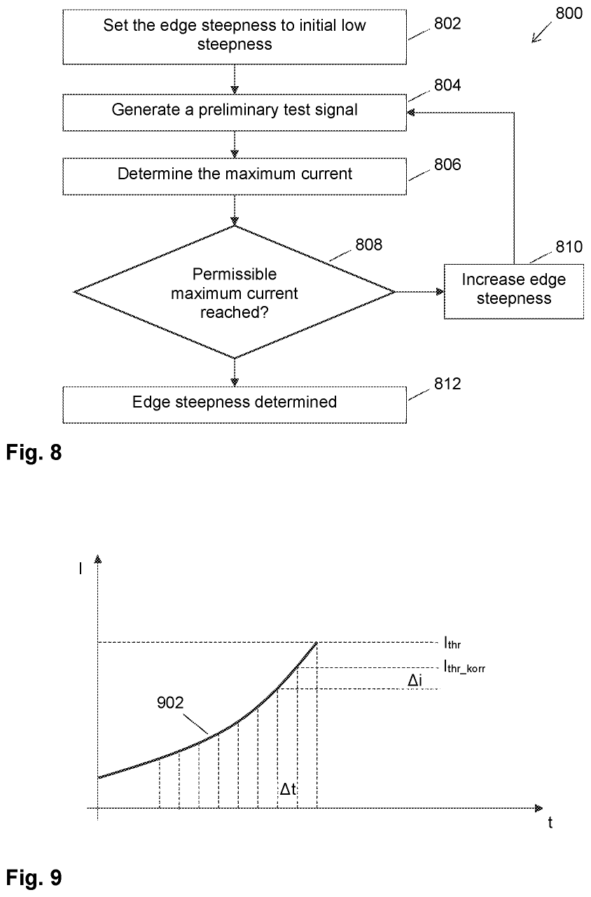

Another procedure for determining edge steepness is described in conjunction with a method 800 shown in FIG. 8. Firstly, in step 802, an edge steepness is set to an initial low steepness. The initial low steepness may, for example, be so low that it does not lead to an overload of the test signal source 102 and does not impair the measurement results, even in the case of transformers with a very high parasitic capacitance (for example, 3 μF). If, for example, the capacitive current is to remain below 100 mA, the initial low edge steepness according to equation (1) can be set to 50 V/1500 μs, for example, so that the test signal source is not overloaded even with a parasitic capacitance of 3 μF. With this edge steepness, a preliminary test signal is generated (step 804) and the maximum occurring current is determined in step 806. If the maximum occurring current is less than the permissible maximum current, for example, less than the nominal current of the test signal source 102 (step 808), the preliminary edge steepness can be increased in step 810, for example, by a certain value or percentage. The method is repeatedly continued with the new preliminary edge steepness in step 804. If the permissible maximum current is reached in step 808, the edge steepness to be used for testing the transformer 180 can be determined in step 812; for example, the edge steepness at which the permissible maximum current has not yet been reached can be used.

As described above, the test signal may be a periodic signal. A frequency can be predetermined, for example, through test conditions; for example, the test signal can have the nominal frequency of the transformer or a multiple thereof as the fundamental frequency. The fundamental frequency of the test signal may also be less than the nominal frequency of the transformer. However, in particular when measuring the magnetization curve of the transformer, it may be necessary to feed the highest possible current in order to generate the highest possible magnetic flux in the transformer 180. As soon as this high current is reached, the polarity of the applied voltage signal must be switched in order to generate the highest possible current and thus high magnetic flux in the transformer in the opposite direction. This process can be repeated several times in succession when recording the magnetization curve. For this purpose, a comparator can be provided, which, for example, using software in the processing device 104 compares the actual current from the current measuring device 108 with a threshold current, which corresponds, for example, to the nominal current of the test signal source 102. Due to the reduced edge steepness, however, the polarity reversal is delayed because a certain time elapses during the dropping or rising edge until the voltage reaches the zero crossing and reduces the inductive current flow and thus the magnetic flux, whereby the current can exceed the threshold current. To avoid this, reaching the threshold current may be predicted as follows.

FIG. 9 shows, by way of example, a non-linear current course 902 over time, which flows as an inductive current through a winding of the transformer 180 due to the voltage applied to the transformer 180. The current course 902 is more non-linear because they are generally saturating inductances. The inductance value is therefore unknown and current-dependent. Thus, the slope of the current course 902 is also not known. Therefore, a continuous determination of the slope of the current course 902 is performed. For example, the current may be sampled at successive points in time (for example, at the vertical dashed lines shown in FIG. 9) and thus a Ai/At of the current course may be continuously determined in real time. A delay ta between the beginning of an edge and the zero crossing can be determined due to the edge steepness from the voltage swing and the set edge steepness. From the desired maximum current Iₜₕᵣ, a corrected maximum current I_{thr_corr} can be determined from the actual slope of the current Ai/At as follows:

$${I}_{thr \_ corr = {I}_{thr} - \frac{Δ i}{Δ t} {t}_{d}} \qquad ( equation 2 )$$

As soon as the measured current reaches the corrected maximum current I_{thr_corr}, the polarity reversal process is initiated with the determined edge steepness, so that the maximum current Iₜₕᵣ is not exceeded.

Of course, the features of the above-described embodiments and aspects of the invention may be combined with one another. In particular, the features can be used not only in the described combinations, but also in other combinations or on their own, without departing from the scope of the invention.

1. A method for testing a transformer, comprising:
determining an edge steepness for a test signal as a function of the transformer to be tested,
generating the test signal with the determined edge steepness, and
testing the transformer using the generated test signal,
wherein determining the edge steepness comprises:
determining a parasitic capacitance of the transformer,
determining the edge steepness as a function of the parasitic capacitance and a predetermined maximum capacitive current which can occur during testing of the transformer.

2. (canceled)

3. The method according to claim 1, wherein determining the parasitic capacitance comprises:
measuring the parasitic capacitance by means of a high-frequency measurement on the transformer, and/or
acquiring an input of the parasitic capacitance from a user.

4. The method according to claim 1, wherein the test signal is a periodic test signal, wherein determining the edge steepness comprises an iterative method, in which based on an edge steepness in a period of the test signal, a subsequent edge steepness for a subsequent period of the test signal is determined as a function of a measured maximum current generated during testing of the transformer with the test signal.

5. The method according to claim 1, wherein a time at which an edge of the test signal begins is adjusted as a function of a comparison of a current generated by the test signal through the transformer with a threshold value.

6. The method according to claim 5, wherein the amount of the threshold value is less than an amount of a maximum nominal current of a device providing the test signal.

7. The method according to claim 5, wherein the test signal comprises a voltage signal, and the threshold value is determined as a function of the edge steepness of the test signal, a voltage swing of the test signal, and an absolute current rise of a current generated by the test signal through the transformer.

8. The method according to claim 7, wherein the current rise of the current generated by the test signal is determined continuously during testing of the transformer.

9. The method according to claim 8, wherein the threshold value is determined as a difference between an amount of a desired maximum current generated by the test signal through the transformer and a product of the actual current rise and a polarity reversal time of the test signal that depends on the voltage swing of the test signal and the edge steepness.

10. (canceled)

11. The method according to claim 1, wherein the test signal is a periodic voltage signal, and the periodic voltage signal per period comprises:
a voltage rise with the determined edge steepness from a lower voltage value to an upper voltage value,
an upper portion with substantially constant voltage at the upper voltage value,
a voltage drop from the upper voltage value to the lower voltage value, and
a lower portion with substantially constant voltage at the lower voltage value.

12. (canceled)

13. The method according to claim 1, wherein testing the transformer comprises determining a magnetization curve of the transformer as a function of the test signal and of a time course of a current generated by the test signal through the transformer.

14. (canceled)

15. A device for testing a transformer, comprising:
a test signal source for generating a test signal for the transformer,
a processing device coupled to the test signal source and configured,
to determine an edge steepness for the test signal as a function of the transformer to be tested,
to generate the test signal with the determined edge steepness by means of the test signal source, and
to test the transformer using the generated test signal,
wherein determining the edge steepness comprises:
determining a parasitic capacitance of the transformer,
determining the edge steepness as a function of the parasitic capacitance and a predetermined maximum capacitive current which can occur during testing of the transformer.

16. (canceled)

17. A method for testing a transformer, comprising:
determining an edge steepness for a test signal as a function of the transformer to be tested,
generating the test signal with the determined edge steepness, and
testing the transformer using the generated test signal,
wherein the test signal is a periodic test signal, wherein determining the edge steepness comprises an iterative method, in which, based on an edge steepness in a period of the test signal, a subsequent edge steepness for a subsequent period of the test signal is determined as a function of a measured maximum current generated during testing of the transformer with the test signal.

18. The method according to claim 17, wherein determining the edge steepness comprises:
determining a parasitic capacitance of the transformer,
determining the edge steepness as a function of the parasitic capacitance and a predetermined maximum capacitive current which can occur during testing of the transformer.

19. The method according to claim 17, wherein a time at which an edge of the test signal begins is adjusted as a function of a comparison of a current generated by the test signal through the transformer with a threshold value.

20. The method according to claim 19, wherein the amount of the threshold value is less than an amount of a maximum nominal current of a device providing the test signal.

21. The method according to claim 19, wherein the test signal comprises a voltage signal, and the threshold value is determined as a function of the edge steepness of the test signal, a voltage swing of the test signal, and an absolute current rise of a current generated by the test signal through the transformer.

22. The method according to claim 21, wherein the threshold value is determined as a difference between an amount of a desired maximum current generated by the test signal through the transformer and a product of the actual current rise and a polarity reversal time of the test signal that depends on the voltage swing of the test signal and the edge steepness.

23. The method according to claim 17, wherein the test signal is a periodic voltage signal, the periodic voltage signal per period comprises:
a voltage rise with the determined edge steepness from a lower voltage value to an upper voltage value,
an upper portion with substantially constant voltage at the upper voltage value,
a voltage drop from the upper voltage value to the lower voltage value, and
a lower portion with substantially constant voltage at the lower voltage value.

24. The method according to claim 17, wherein testing the transformer comprises determining a magnetization curve of the transformer as a function of the test signal and of a time course of a current generated by the test signal through the transformer.

25. A device for testing a transformer, comprising:
a test signal source for generating a test signal for the transformer,
a processing device coupled to the test signal source and configured,
to determine an edge steepness for the test signal as a function of the transformer to be tested,
to generate the test signal with the determined edge steepness by means of the test signal source, and
to test the transformer using the generated test signal,
wherein the test signal is a periodic test signal, wherein determining the edge steepness comprises an iterative method, in which, based on an edge steepness in a period of the test signal, a subsequent edge steepness for a subsequent period of the test signal is determined as a function of a measured maximum current generated during testing of the transformer with the test signal.
